(19) United States
(12) Patent Application Publication
(10) Pub. No.: US 2015/0028440 A1
(43) Pub. Date: Jan. 29, 2015

(54) MAGNETORESISTIVE DEVICE AND METHOD OF FORMING THE SAME

(71) Applicant: Agency for Science, Technology and Research, Singapore (SG)

(72) Inventors: Ruisheng Liu, Singapore (SG); Hao Meng, Singapore (SG); Vinayak Bharat Naik, Singapore (SG); Cheow Hin Sim, Singapore (SG)

(21) Appl. No.: 14/341,254

(22) Filed: Jul. 25, 2014

(30) Foreign Application Priority Data
Jul. 26, 2013 (SG) 201305731-0

(51) Int. Cl. H01L 43/10; H01L 43/12; H01L 27/22; H01L 43/02

(52) U.S. Cl. CPC H01L 43/10; H01L 43/02; H01L 43/12; H01L 27/222
USPC 257/421; 438/3

(57) ABSTRACT

According to embodiments of the present invention, a magnetoresistive device is provided. The magnetoresistive device includes a free magnetic layer structure having a magnetization orientation that is variable, and a spin orbit coupling structure including a tunnel barrier including a metal oxide, and a metal layer, wherein the tunnel barrier and the metal layer are arranged one over the other, wherein the spin orbit coupling structure is adapted to generate, in response to an applied current, a field to interact with the free magnetic layer structure for switching the magnetization orientation of the free magnetic layer structure. According to further embodiments of the present invention, a method of forming a magnetoresistive device is also provided.

### CROSS-REFERENCE TO RELATED APPLICATION

This application claims the benefit of priority of Singapore patent application No. 201305731-0, filed 26 Jul. 2013, the content of it being hereby incorporated by reference in its entirety for all purposes.

### TECHNICAL FIELD

Various embodiments relate to a magnetoresistive device and a method of forming the magnetoresistive device.

### BACKGROUND

The most challenging issue for spin-transfer torque magnetic random access memory (STT MRAM) is to reduce the switching current density (Jc) while still maintaining its thermal stability (Δ) as the memory cell shrinks in size.

The switching current density, J_{c0}, may be defined as below:

$$\begin{matrix}In plane \text{:} {J}_{c 0} = \frac{2 e α {t}_{F} ( 2 {M}_{S} {H}_{K} + 2 {πM}_{S}^{2} )}{ℏη} , & ( Equation 1 ) \\ Out of plane \text{:} {J}_{c 0} = \frac{4 e α {t}_{F} {M}_{S} {H}_{K}}{ℏη} , & ( Equation 2 )\end{matrix}$$

where e=the elementary charge of an electron, α=Gilbert damping constant, t_{F}=the thickness of the free layer, M_{S}=saturation magnetization, H_{K}=anisotropy field, h̅=reduced Planck constant, and η=spin polarization constant.

The thermal stability, Δ, may be defined as below:

$$Δ = \frac{{M}_{S} {H}_{K} V}{2 {k}_{B} T} , \qquad ( Equation 3 )$$

where where M_{S}=saturation magnetization, H_{K}=anisotropy field, V=magnetic layer volume, k_{B}=Boltzmann constant, T=temperature.

Considerations for spin-transfer torque magnetic random access memory (STT MRAM) implementation includes low write current density (Jc) to provide low power consumption, high tunnel magnetoresistive (TMR) to provide enough sense margin, and high thermal stability (Δ=KᵤV/k_{B}T, where Kᵤ=magnetic anisotropy constant, V=magnetic layer volume, k_{B}=Boltzmann constant, T=temperature) to allow long data retention.

There is therefore need to reduce the critical switching current density, to maintain a good thermal stability, and to have low resistance-area (RA) and good tunnel magnetoresistive (TMR).

### SUMMARY

According to an embodiment, a magnetoresistive device is provided. The magnetoresistive device may include a free magnetic layer structure having a magnetization orientation that is variable, and a spin orbit coupling structure including a tunnel barrier including a metal oxide, and a metal layer, wherein the tunnel barrier and the metal layer are arranged one over the other, wherein the spin orbit coupling structure is adapted to generate, in response to an applied current, a field to interact with the free magnetic layer structure for switching the magnetization orientation of the free magnetic layer structure.

According to an embodiment, a method of forming a magnetoresistive device is provided. The method may include forming a free magnetic layer structure having a magnetization orientation that is variable, and forming a spin orbit coupling structure including a tunnel barrier including a metal oxide, and a metal layer, wherein the tunnel barrier and the metal layer are arranged one over the other, wherein the spin orbit coupling structure is adapted to generate, in response to an applied current, a field to interact with the free magnetic layer structure for switching the magnetization orientation of the free magnetic layer structure.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a magnetoresistive device, according to various embodiments.

FIG. 1B shows a flow chart illustrating a method of forming a magnetoresistive device, according to various embodiments.

FIG. 2A shows a schematic cross-sectional view of a conventional magnetoresistive device.

FIG. 2B shows a schematic cross-sectional view of a magnetoresistive device, according to various embodiments.

FIG. 3A shows a schematic cross-sectional view of a magnetoresistive device, according to various embodiments.

FIG. 3B shows a schematic cross-sectional view of a magnetoresistive device, according to various embodiments.

FIGS. 4A and 4B show plots of resistance versus magnetic field loop for the magnetoresistive devices of the embodiments of FIGS. 3A and 3B respectively.

FIGS. 5A and 5B show plots of resistance versus pulsed current for the magnetoresistive devices of the embodiments of FIGS. 3A and 3B respectively.

FIGS. 6A and 6B show plots of current versus pulse width for the magnetoresistive devices of the embodiments of FIGS. 3A and 3B respectively.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may provide magnetic stacks for spin-transfer torque magnetic random access memory (STT MRAM) with low switching current density.

Various embodiments may reduce the switching current density for STT MRAM.

Various embodiments may provide a magnetic tunnel junction (MTJ) stack for spin-transfer torque magnetic random access memory (STT MRAM), which may achieve a reduction of switching current density (Jc) by about approximately 42% in comparison with a conventional memory structure, while keeping the thermal stability (Δ) unaffected. This may mean that various embodiments may enable a reduction in the switching current density (Jc) while maintaining its thermal stability (Δ).

In the magnetoresistive device of various embodiments, an insertion structure may be provided, sandwiched between a free layer and an electric lead layer (e.g. an electrode or contact). The insertion structure may include a dusting heavy metal layer (e.g. tantalum (Ta), platinum (Pt), palladium (Pd), gold (Au), etc.), a tunnel barrier layer (e.g. magnesium oxide (MgO)) and a heavy metal layer (e.g. tantalum (Ta), platinum (Pt), palladium (Pd), gold (Au), etc.). In some embodiments, the insertion structure may not include the dusting heavy metal layer. In various embodiments, the term “dusting” as applied to a layer may refer to a very thin layer being deposited, for example about 1 nm or less. Further, the term “dusting” may refer to the process of creating a layer that may not be continuous, by adding a few atoms.

In various embodiments, the thickness (t1) of the dusting heavy metal layer may vary from about 0.1 nm to about 1.0 nm and/or the thickness (t2) of the tunnel barrier layer (e.g. MgO) may vary from about 0.5 nm to about 1.0 nm.

The insertion structure intrinsically may be a strong spin orbit coupling system or structure, such that an effective field may be induced when passing a current through the insertion structure or the magnetoresistive device, which may assist the switching of the free layer's magnetization in conjunction with the spin transfer torque effect. This stack design of various embodiments may be applied to both in-plane and perpendicular STT MRAMs. A spin-orbit coupling system or structure may refer to a structure in which an element with a strong spin-orbit interaction (such as Pt, Pd, Au, Ta, etc.) may be placed in contact or alloyed with the magnetic free layer.

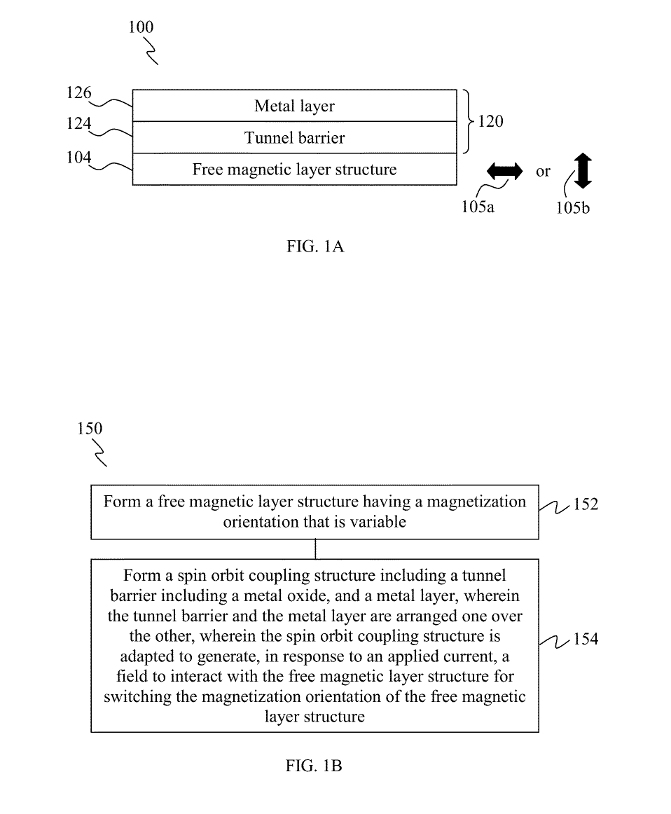

FIG. 1A shows a schematic cross-sectional view of a magnetoresistive device 100, according to various embodiments. The magnetoresistive device 100 includes a free magnetic layer structure 104 having a magnetization orientation (as represented by the double-headed arrows 105a or 105b) that is variable, and a spin orbit coupling structure 120 including a tunnel barrier 124 including a metal oxide, and a metal layer 126, wherein the tunnel barrier 124 and the metal layer 126 are arranged one over the other, wherein the spin orbit coupling structure 120 is adapted to generate, in response to an applied current, a field to interact with the free magnetic layer structure 104 for switching the magnetization orientation 105a, 105b of the free magnetic layer structure 104.

In other words, a magnetoresistive device 100 may be provided. The magnetoresistive device 100 may include a free magnetic layer structure 104 where the magnetization orientation 105a, 105b of the free magnetic layer structure 104 may be changeable or switchable. The magnetoresistive device 100 may further include a spin orbit coupling (SOC) structure (or spin-orbit interaction (SOI) structure) 120, where the free magnetic layer structure 104 and the spin orbit coupling structure 120 may be arranged one over the other. For example, the spin orbit coupling structure 120 may be arranged over the free magnetic layer structure 104. Therefore, the magnetoresistive device 100 may have a stack arrangement of the free magnetic layer structure 104 and the spin orbit coupling structure 120. The spin orbit coupling structure 120 may be capable of inducing spin orbit coupling interactions. The spin orbit coupling structure 120 may include a spacer layer, for example in the form of a tunnel barrier 124 which may include a metal oxide, and a metal layer 126. When a current is applied to the magnetoresistive device 100, and therefore also to the spin orbit coupling structure 120, the spin orbit coupling structure 120 may generate a field (e.g. a magnetic field) which may act on or interact with the free magnetic layer structure 104 to assist in the switching of the magnetization orientation 105a, 105b of the free magnetic layer structure 104. This may mean that the spin orbit coupling structure 120 may generate a field or an effective field to interact with the free magnetic layer structure 104 to switch the magnetization orientation 105a, 105b of the free magnetic layer structure 104.

In the context of various embodiments, the metal layer 126 may include a material (metal) with a strong spin-orbit interaction. In other words, the spin orbit coupling structure 120 may include a material with a strong spin-orbit interaction.

In the context of various embodiments, the spin orbit coupling structure 120 may enable a strong hybridization between the free magnetic layer structure 104 (e.g. the iron (Fe) atoms of the free magnetic layer structure 104) and the O atoms of the metal oxide of the tunnel barrier 124.

In the context of various embodiments, the spin orbit coupling structure 120 may include a ferromagnetic layer, a metal layer (e.g. 126) and a tunnel barrier (e.g. 124), for example an arrangement of ferromagnetic layer/Ta (or Pt, Pd, Au, etc)/MgO.

In the context of various embodiments, the metal oxide of the tunnel barrier 124 may be or may include magnesium oxide (MgO). However, it should be appreciated that other metal oxides may be used, for example aluminium oxide. In various embodiments, the magnetoresistive device 100 having the spin orbit coupling structure 120 including a tunnel barrier 124 having MgO may exhibit interfacial electronic structures or states, and also spin-orbit interactions, that are different from magnetoresistive devices having aluminium oxide. The magnetoresistive device 100 having a MgO tunnel barrier 124 may provide a stronger effect and thus assist the switching of the magnetization orientation of the free magnetic layer structure 104 more effectively.

In the context of various embodiments, the term “free magnetic layer structure” may mean a magnetic layer structure having a variable or switchable magnetization orientation. In other words, the magnetization orientation may be varied or switched, for example in response to an electrical signal (e.g. current) and/or a magnetic field applied to the magnetoresistive device. The magnetization orientation of the free magnetic layer structure may be varied, depending on the degree or amount of the magnetization reversal field (or current). The free magnetic layer structure may include a soft ferromagnetic material. The soft ferromagnetic material may be receptive to magnetization and demagnetization (i.e. easily magnetized and demagnetized), and may have a small hysteresis loss and a low coercivity, in comparison to a fixed magnetic layer structure. In the context of various embodiments, a free magnetic layer structure may also be referred to as a “soft layer”, a “soft magnetic layer” or a “ferromagnetic soft layer”. In the context of various embodiments, the free magnetic layer structure may act as a storage layer.

In various embodiments, the metal layer 126 may include a heavy metal. This may mean that the metal layer 126 may be a heavy metal layer.

In the context of various embodiments, the term “heavy metal” may refer to metals or elements with a large atomic mass or weight, which may be favorable for triggering large spin-orbit coupling. In other words, the term “heavy metal” may refer to metals or elements with a high spin-orbit interaction component. Such metals or elements are heavy as spin-orbit is a function of the atomic weight. Non-limiting examples of heavy metals may include but not limited to tantalum (Ta), platinum (Pt), palladium (Pd) or gold (Au).

In various embodiments, the spin orbit coupling structure 120 may be arranged in between the free magnetic layer structure 104 and an electrode (e.g. a top electrode) of the magnetoresistive device 100.

In various embodiments, the spin orbit coupling structure 120 may be arranged in contact (e.g. in direct contact) with the free magnetic layer structure 104. This may mean that an interface may be defined between the spin orbit coupling structure 120 and the free magnetic layer structure 104.

In various embodiments, the tunnel barrier 124 may be arranged proximal to the free magnetic layer structure 104.

In various embodiments, the spin orbit coupling structure 120 may have a width that is at least substantially similar or identical to a width of the free magnetic layer structure 104.

In various embodiments, the magnetoresistive device 100 may further include a first electrode (e.g. a top electrode), and a second electrode (e.g. a bottom electrode), wherein the spin orbit coupling structure 120 and the free magnetic layer structure 104 may be arranged in between the first and second electrodes, and wherein the spin orbit coupling structure 120 may be arranged in between the free magnetic layer structure 104 and the first electrode. The spin orbit coupling structure 120 may be arranged in contact (e.g. in direct contact) with the free magnetic layer structure 104. The spin orbit coupling structure 120 may be arranged in contact (e.g. in direct contact) with the first electrode. This may mean that an interface may be defined between the spin orbit coupling structure 120 and the first electrode.

In the context of various embodiments, the metal layer 126 may include at least one of tantalum (Ta), platinum (Pt), palladium (Pd) or gold (Au).

In the context of various embodiments, the metal layer 126 may include or consist of tantalum (Ta).

In various embodiments, the spin orbit coupling structure 120 may further include an additional metal layer, wherein the tunnel barrier 124 may be arranged in between the metal layer 126 and the additional metal layer. The additional metal layer may include a heavy metal. The additional metal layer may be a dusting metal layer (e.g. a dusting heavy metal layer). In the context of various embodiments, the term “dusting” as applied to a layer (i.e. a dusting layer) may refer to a very thin layer being deposited, for example about 1 nm or less.

In various embodiments, the additional metal layer may be arranged proximal to the free magnetic layer structure 104. The tunnel barrier 124 may be arranged on or over the additional metal layer.

In various embodiments, the additional metal layer may be arranged in contact (e.g. in direct contact) with the free magnetic layer structure 104.

In various embodiments, the additional metal layer may have a thickness that is less than a thickness of the metal layer 126.

In various embodiments, the additional metal layer may have a thickness in a range of between about 0.1 nm and about 1.0 nm, for example between about 0.1 nm and about 0.5 nm, about 0.1 nm and about 0.3 nm, about 0.5 nm and about 1.0 nm, or about 0.3 nm and about 0.8 nm, e.g. about 0.1 nm, about 0.3 nm, or about 0.5 nm.

In the context of various embodiments, the additional metal layer may include at least one of tantalum (Ta), platinum (Pt), palladium (Pd) or gold (Au).

In the context of various embodiments, the additional metal layer may include or consist of tantalum (Ta).

In various embodiments, the tunnel barrier 124 may have a thickness in a range of between about 0.5 nm and about 1.0 nm, for example between about 0.5 nm and about 0.8 nm, between about 0.7 nm and about 1.0 nm or between about 0.6 nm and about 0.8 nm, e.g. about 0.5 nm, about 0.8 nm or about 1.0 nm.

In various embodiments, the metal layer 126 may have a thickness in a range of between about 1.0 nm and about 10 nm, for example between about 1 nm and about 5 nm, between about 1 nm and about 3 nm, between about 5 nm and about 10 nm, or between about 3 nm and about 7 nm.

In various embodiments, the magnetoresistive device 100 may further include a fixed magnetic layer structure having a fixed magnetization orientation, wherein the fixed magnetic layer structure and the free magnetic layer structure 104 may be arranged one over the other.

In the context of various embodiments, the term “fixed magnetic layer structure” may mean a magnetic layer structure having a fixed magnetization orientation. The fixed magnetic layer structure may include a hard ferromagnetic material or a soft ferromagnetic material. The ferromagnetic material of the fixed magnetic layer structure may be resistant to magnetization and demagnetization (i.e. not easily magnetized and demagnetized), and may have a high hysteresis loss and a high coercivity as its magnetization may be fixed or pinned. In the context of various embodiments, a fixed magnetic layer structure may be referred to as a “hard layer”, a “hard magnetic layer” or a “ferromagnetic hard layer”. In the context of various embodiments, the fixed magnetic layer structure may act as a reference layer.

In various embodiments, the magnetoresistive device 100 may further include a spacer layer (or separation layer) arranged in between the fixed magnetic layer structure and the free magnetic layer structure 104. The spacer layer may be a tunnel barrier, for example a magnesium oxide (MgO) tunnel barrier.

In the context of various embodiments, the free magnetic layer structure 104 may include copper-iron-boron (CoFeB).

In the context of various embodiments, the magnetoresistive device 100 may have perpendicular anisotropy (i.e. a perpendicular magnetoresistive device). This may mean that the magnetization orientation 105b of the free magnetic layer structure 104 may be perpendicular to the plane of a major surface of the free magnetic layer structure 104. This may also mean that the magnetization orientation 105b of the free magnetic layer structure 104 may be aligned or oriented at least substantially parallel to a thickness direction of the free magnetic layer structure 104 (and also that of the magnetoresistive device 100). In other words, the free magnetic layer structure 104 may have an easy axis at least substantially parallel to a thickness direction of the free magnetic layer structure 104. Further, the fixed magnetization orientation of the fixed magnetic layer structure may be aligned or oriented at least substantially parallel to a thickness direction of the fixed magnetic layer structure (and also that of the magnetoresistive device 100).

In the context of various embodiments, the magnetoresistive device 100 may have in-plane anisotropy (i.e. an in-plane magnetoresistive device). This may mean that the magnetization orientation 105a of the free magnetic layer structure 104 may be parallel to the plane of a major surface of the free magnetic layer structure 104. This may also mean that the magnetization orientation 105a of the free magnetic layer structure 104 may be aligned or oriented at least substantially perpendicular to a thickness direction of the free magnetic layer structure 104 (and also that of the magnetoresistive device 100). In other words, the free magnetic layer structure 104 may have an easy axis at least substantially perpendicular to a thickness direction of the free magnetic layer structure 104. Further, the fixed magnetization orientation of the fixed magnetic layer structure may be aligned or oriented at least substantially perpendicular to a thickness direction of the fixed magnetic layer structure (and also that of the magnetoresistive device 100).

In the context of various embodiments, the term “easy axis” as applied to magnetism may mean an energetically favorable direction of spontaneous magnetization as a result of magnetic anisotropy. The magnetization orientation may be either of two opposite directions along the easy axis.

In the context of various embodiments, the resistance state of the magnetoresistive device 100 may change as a result of a change in its resistivity.

In the context of various embodiments, the magnetization orientation of the free magnetic layer structure 104 may be in one of two directions. The free magnetic layer structure 104 may be in a parallel state (P) or an anti-parallel state (AP) with respect to a fixed magnetic layer structure. In the parallel (P) state, the magnetization orientation of the free magnetic layer structure 104 is parallel to the magnetization orientation of the fixed magnetic layer structure, such that the two magnetization orientations are in the same direction. In the anti-parallel (AP) state, the magnetization orientation of the free magnetic layer structure 104 is anti-parallel to the magnetization orientation of the fixed magnetic layer structure, such that the two magnetization orientations are in opposite directions. In the parallel (P) state, the magnetoresistive device 100 may have a low resistivity, and hence low resistance, to define a “0” state or value. In the anti-parallel (AP) state, the magnetoresistive device 100 may have a high resistivity, and hence high resistance, to define a “1” state or value.

In the context of various embodiments, the free magnetic layer structure 104 and the spin orbit coupling structure 120 may be part of or form part of a magnetic junction (or magnetic tunnel junction (MTJ)) of the magnetoresistive device 100. The fixed magnetic layer structure may also be part of or form part of the magnetic junction (or magnetic tunnel junction).

In the context of various embodiments, the magnetoresistive device 100 may be a a tunnel magnetoresistive (TMR) device.

In the context of various embodiments, the magnetoresistive device 100 may be or may form part of a memory device, e.g. a magnetic random access memory (MRAM), e.g. a spin-transfer torque magnetic random access memory (STT-MRAM).

In the context of various embodiments, the magnetoresistive device 100 may be or may include a spin-transfer torque magnetic random access memory (STT-MRAM). The STT-MRAM may exhibit or induce or generate a spin transfer torque effect (e.g. in response to an applied current), and the spin orbit coupling structure 120 may generate, in response to an applied current, a field to interact with the free magnetic layer structure 104 for switching the magnetization orientation of the free magnetic layer structure 104 in cooperation or in combination with the spin transfer torque effect. This may mean that the spin transfer torque effect and the field generated may cooperate or combine to switch the magnetization orientation of the free magnetic layer structure 104. The spin transfer torque effect and the field may be generated or induced in response to the same applied current. A spin orbit coupling structure 120 incorporating a MgO tunnel barrier 124 may show effect(s) favorable for assisting spin-transfer torque (STT) switching. However, it should be appreciated that other metal oxide structures possessing a similar effect on STT switching may also be used.

In the context of various embodiments, the magnetoresistive device 100 may have an arrangement of MgO/CoFeB/Ta (or Pt, Pd etc)/MgO/Ta (or Pt, Pd, etc) which may assist the STT MRAM switching.

FIG. 1B shows a flow chart 150 illustrating a method of forming a magnetoresistive device, according to various embodiments.

At 152, a free magnetic layer structure having a magnetization orientation that is variable is formed.

At 154, a spin orbit coupling structure is formed, the spin orbit coupling structure including a tunnel barrier comprising a metal oxide, and a metal layer, wherein the tunnel barrier and the metal layer are arranged one over the other, wherein the spin orbit coupling structure is adapted to generate, in response to an applied current, a field to interact with the free magnetic layer structure for switching the magnetization orientation of the free magnetic layer structure.

In various embodiments, the spin orbit coupling structure that is formed may further include an additional metal layer, wherein the tunnel barrier may be arranged in between the metal layer and the additional metal layer.

It should be appreciated that descriptions in the context of the magnetoresistive device 100 may correspondingly be applicable to the magnetoresistive device formed by the method of various embodiments, and the associated process steps of the method.

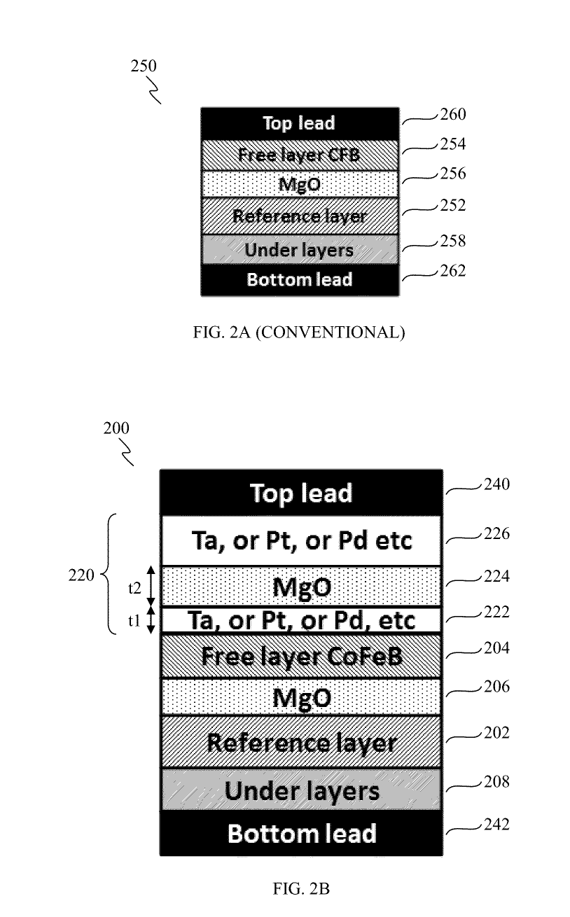

FIG. 2A shows a schematic cross-sectional view of a conventional magnetoresistive device 250. The magnetoresistive device 250 includes a reference layer 252 and a free layer 254, with a magnesium oxide (MgO) layer 256 in between. The free layer 254 may include a material of cobalt-iron-boron (CFB or CoFeB). The magnetoresistive device 250 further includes other layers, collectively represented as “under layers” 258. The reference layer 252, the free layer 254, the MgO layer 256 and the under layers 258 are sandwiched between a top lead 260 and a bottom lead 262.

FIG. 2B shows a schematic cross-sectional view of a magnetoresistive device (e.g. STT MRAM) 200, according to various embodiments. The magnetoresistive device 200 may be or may include a stack structure, e.g. a magnetic tunnel junction (MTJ) stack.

The magnetoresistive device 200 may include a reference layer 202 and a free layer 204, with a tunnel barrier layer (e.g. magnesium oxide (MgO)) 206 in between the reference layer 202 and the free layer 204. The free layer 204 may be arranged over or above the reference layer 202. The free layer 204 may include a material of cobalt-iron-boron (CoFeB). The magnetoresistive device 200 may include one or more further layers, collectively represented as “under layers” 208. The under layers 208 may be arranged below or beneath the reference layer 202.

The reference layer 202, the free layer 204, the MgO layer 206 and the under layers 208 may be sandwiched between a top lead or top electric lead layer (also known as top electrode or top contact) 240 and a bottom lead or bottom electric lead layer (also known as bottom electrode or bottom contact) 242.

The magnetoresistive device 200 may further include a spin orbit coupling structure (or insertion structure) 220 sandwiched between the free layer 204 and one of the electrodes, for example the top electrode 240. The spin orbit coupling structure 220 may be in contact (e.g. direct contact) with the free layer 204. The spin orbit coupling structure 220 and the free layer 204 may define an interface therebetween. The spin orbit coupling structure 220 may have at least substantially similar or identical width as that of the free layer 204. For example, the entire spin orbit coupling structure 220 may have at least substantially similar or identical width as that of the free layer 204. The entire spin orbit coupling structure 220 may have a uniform width. The spin orbit coupling structure 220 may be magnetically coupled and/or electrically coupled with the free layer 204. The spin orbit coupling structure 220 may be in contact (e.g. direct contact) with the top electrode 240. The spin orbit coupling structure 220 and the top electrode 240 may define an interface therebetween.

The spin orbit coupling structure (or insertion structure) 220 may include a S-layer structure. The spin orbit coupling structure 220 may include a dusting heavy metal layer 222, a tunnel barrier layer (e.g. MgO tunnel barrier) 224 and a heavy metal layer 226. The MgO layer 224 may be arranged in between the dusting heavy metal layer 222 and the heavy metal layer 226. Each of the dusting heavy metal layer 222 and the heavy metal layer 226 may include at least one of tantalum (Ta), platinum (Pt), palladium (Pd), or gold (Au). It should be appreciated that other metals may be used. The dusting heavy metal layer 222 may have a thickness that is less than the thickness of the heavy metal layer 226. The thickness (t1) of the dusting layer 222 may be in a range of between about 0.1 nm and about 1.0 nm. The thickness (t2) of the MgO layer 224 may be in a range of between about 0.5 nm to about 1.0 nm. The thickness of the heavy metal layer 226 may be in a range of between about 1.0 nm and about 10 nm.

In some embodiments, it should be appreciated that the spin orbit coupling structure (or insertion structure) 220 may include a 2-layer structure having a tunnel barrier layer (e.g. MgO tunnel barrier) 224 and a heavy metal layer 226.

The spin orbit coupling structure 220 intrinsically may be a strong spin orbit coupling system, such that an effective field may be induced by or from the spin orbit coupling structure 220 when a current is passed through the spin orbit coupling structure 220, which may assist the switching of the magnetization orientation of the free layer 204, in conjunction with the spin transfer torque effect. Therefore, the magnetoresistive device 200 may have a stack with insertion of a strong spin orbit interaction structure 220.

In various embodiments, the magnetoresistive device 200 may have an arrangement of MgO (e.g. 206)/CoFeB (e.g. 204)/Ta (or Pt, Pd etc) (e.g. 222)/MgO (e.g. 224)/Ta (or Pt, Pd, etc) (e.g. 226) which may assist the STT MRAM switching.

The magnetoresistive device 200 may be an in-plane magnetoresistive device (e.g. in-plane STT MRAM) or a perpendicular magnetoresistive device (e.g. perpendicular STT MRAM). This may mean that the spin orbit coupling structure 220 may be provided in an in-plane magnetoresistive device (e.g. in-plane STT MRAM) or a perpendicular magnetoresistive device (e.g. perpendicular STT MRAM). The stack design of various embodiments may be implemented in the stack structure of a perpendicular STT MRAM, which may reduce the associated switching current density (Jc).

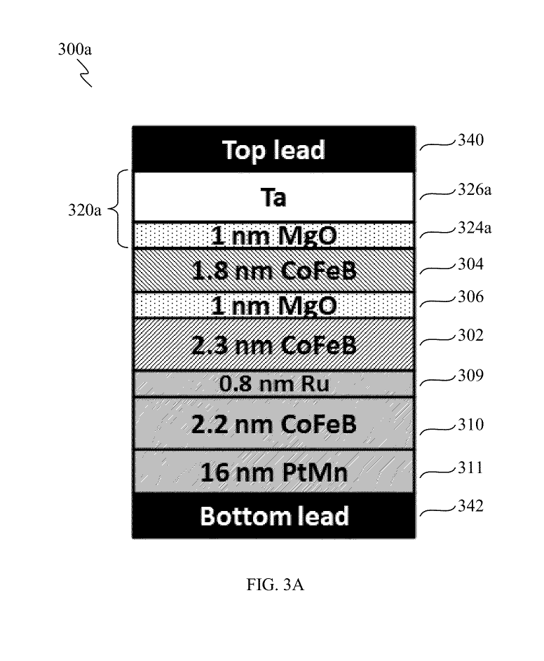

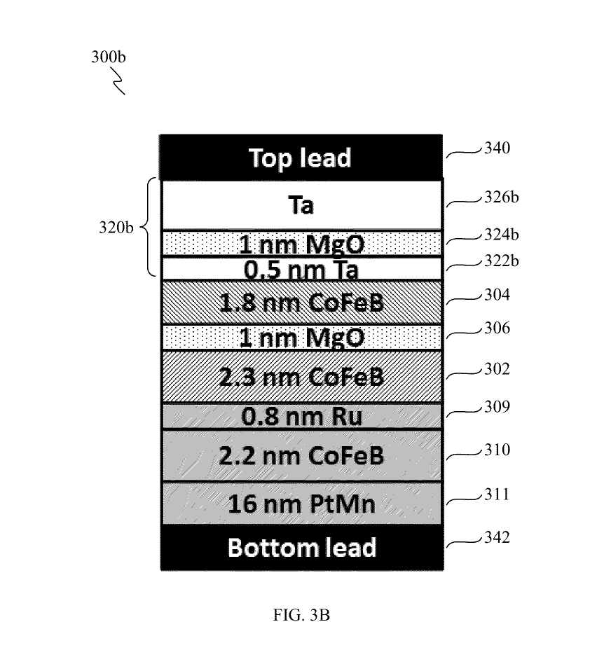

FIGS. 3A and 3B show schematic cross-sectional views of respective magnetoresistive devices (e.g. STT MRAM) 300a, 300b, according to various embodiments. Each magnetoresistive device 300a, 300b may be or may include a stack structure, e.g. a magnetic tunnel junction (MTJ) film stack. Each magnetoresistive device 300a, 300b may be an in-plane magnetoresistive device (e.g. in-plane STT MRAM) or a perpendicular magnetoresistive device (e.g. perpendicular STT MRAM).

Each magnetoresistive device 300a, 300b may include a reference layer 302, which may be a layer of cobalt-iron-boron (CoFeB) of a thickness of about 2.3 nm, and a a free layer 304, which may be a layer of cobalt-iron-boron (CoFeB) of a thickness of about 1.8 nm. Each magnetoresistive device 300a, 300b may further include a magnesium oxide (MgO) layer 306 of a thickness of about 1 nm sandwiched between the reference layer 302 and the free layer 304. The free layer 304 may be arranged over or above the reference layer 302.

Each magnetoresistive device 300a, 300b may further include a ruthenium (Ru) layer 309 of a thickness of about 0.8 nm, a cobalt-iron-boron (CoFeB) layer 310 of a thickness of about 2.2 nm and a platinum-manganese (PtMn) layer 311 of a thickness of about 16 nm arranged beneath or below the reference layer 302. The Ru layer 309 may act as a spacer layer between the reference layer 302 and the CoFeB layer 310. The CoFeB layer 310 is a ferromagnetic layer that may be pinned by the PtMn pinning layer 311. The CoFeB layer 310 may be strongly antiferromagnetically coupled (AFC) to the CoFeB reference layer 302 through the Ru interlayer 309. The pinning layer 311 is used to fix the magnetization orientation of the CoFeB layer 310 in one direction. The CoFeB layer 310 is used to fix the magnetization orientation of the reference layer 302 and offset the stray field of the reference layer 302. In other words, the CoFeB layer 310 may be a pinning magnetic layer the role of which may be to stabilize the reference layer 302. To reinforce the stability, an antiferromagnetic layer 311 (here PtMn) may be added in order to pin the magnetic orientation of the layer 310.

The reference layer 302, the free layer 304 and the MgO layer 306 of each magnetoresistive device 300a, 300b may be arranged between a top lead (also known as top electrode or top contact) 340 and a bottom lead (also known as bottom electrode or bottom contact) 342.

Each magnetoresistive device 300a, 300b may further include a spin orbit coupling structure (or insertion structure) 320a, 320b sandwiched between the free layer 304 and one of the electrodes, for example the top electrode 340. The spin orbit coupling structure 320a, 320b may be in contact (e.g. direct contact) with the free layer 304. The spin orbit coupling structure 320a, 320b and the free layer 304 may define an interface therebetween. The spin orbit coupling structure 320a, 320b may have at least substantially similar or identical width as that of the free layer 304. For example, the entire spin orbit coupling structure 320a, 320b may have at least substantially similar or identical width as that of the free layer 304. The entire spin orbit coupling structure 320a, 320b may have a uniform width. The spin orbit coupling structure 320a, 320b may be magnetically coupled and/or electrically coupled with the free layer 304. The spin orbit coupling structure 320a, 320b may be in contact (e.g. direct contact) with the top electrode 340. The spin orbit coupling structure 320a, 320b and the top electrode 340 may define an interface therebetween.

Referring to FIG. 3A, the spin orbit coupling structure (or insertion structure) 320a of the magnetoresistive device 300a may include a 2-layer structure. The spin orbit coupling structure 320a may include a magnesium oxide (MgO) tunnel barrier 324a of a thickness of about 1 nm, and a tantalum (Ta) layer 326a, without a dusting layer (e.g. Ta layer). Therefore, the magnetoresistive device 300a may include an insertion of 1 nm MgO/Ta. The tantalum (Ta) layer 326a may be arranged over the MgO layer 324a. The MgO layer 324a may be in contact (e.g. direct contact) with the free layer 304. The tantalum (Ta) layer 326a may be in contact (e.g. direct contact) with the top electrode 340. As may be observed in FIG. 3A, the magnetoresistive device 300a has a double MgO stack.

Referring to FIG. 3B, the spin orbit coupling structure (or insertion structure) 320b of the magnetoresistive device 300b may include a 3-layer structure. The spin orbit coupling structure 320b may include a magnesium oxide (MgO) tunnel barrier 324b of a thickness of about 1 nm, a tantalum (Ta) layer 326b, and a tantalum (Ta) dusting layer 322b of a thickness of about 0.5 nm. Therefore, the magnetoresistive device 300b may include an insertion of 0.5 nm Ta/1 nm MgO/Ta. The MgO layer 324b may be arranged in between the Ta dusting layer 322b and the Ta layer 326b. The tantalum (Ta) layer 326b may be arranged over the MgO layer 324b, which in turn may be arranged over the Ta dusting layer 322b. The Ta dusting layer 322b may be in contact (e.g. direct contact) with the free layer 304. The tantalum (Ta) layer 326b may be in contact (e.g. direct contact) with the top electrode 340. As may be observed in FIG. 3B, the magnetoresistive device 300b has a double MgO stack with a Ta dusting layer 322b.

In various embodiments, the layer 310 of each magnetoresistive device 300a, 300b may be a cobalt-iron (CoFe) layer of a thickness of about 2.2 nm.

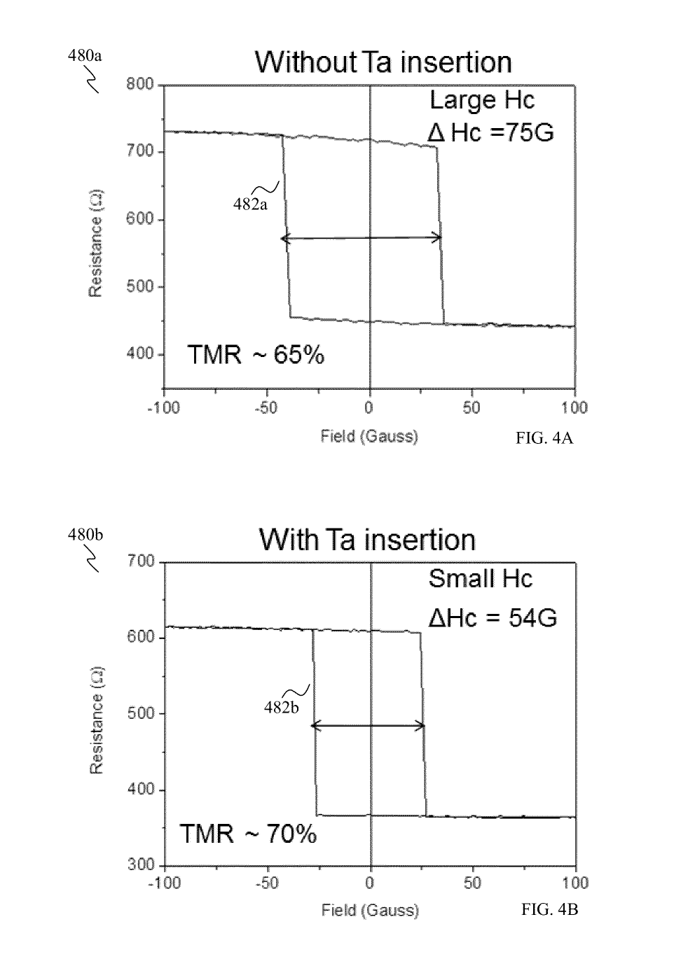

FIGS. 4A and 4B show plots 480a, 480b of resistance (R) versus magnetic field (H) loop for the magnetoresistive devices 300a, 300b of the embodiments of FIGS. 3A and 3B respectively. The device size is approximately 120 nm×240 nm, and processed based on annealing at about 300° C. in a 1 T field for about 2 hours. Plot 480a shows a R-H loop 482a corresponding to the magnetoresistive device 300a without a tantalum (Ta) dusting layer, while plot 480b shows a R-H loop 482b corresponding to the magnetoresistive device 300b with a tantalum (Ta) dusting layer 322b.

As indicated in FIGS. 4A and 4B, the magnetoresistive device 300a may exhibit a tunnel magnetoresistive (TMR) value of about 65% and a large switching field, Hc, with ΔHc of about 75 G, while the magnetoresistive device 300b may exhibit a tunnel magnetoresistive (TMR) value of about 70% and a small switching field, Hc, with ΔHc of about 54 G.

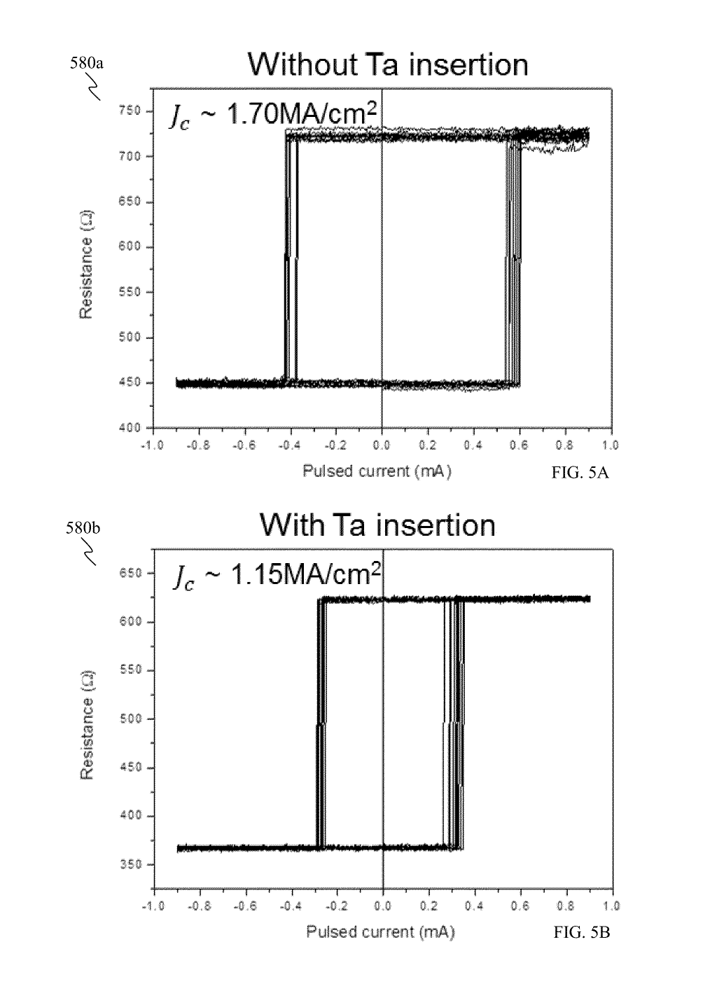

FIGS. 5A and 5B show plots 580a, 580b of resistance versus pulsed current for the magnetoresistive devices 300a, 300b of the embodiments of FIGS. 3A and 3B respectively, illustrating spin transfer torque switching at a pulse width of about 100 ms. Plot 580a shows the results corresponding to the magnetoresistive device 300a without a tantalum (Ta) dusting layer, while plot 580b shows the results corresponding to the magnetoresistive device 300b with a tantalum (Ta) dusting layer 322b.

As indicated in FIGS. 5A and 5B, the magnetoresistive device 300a may exhibit a switching current density, J_{c}, of about 1.70 MA/cm², while the magnetoresistive device 300b may exhibit a switching current density, J_{c}, of about 1.15 MA/cm².

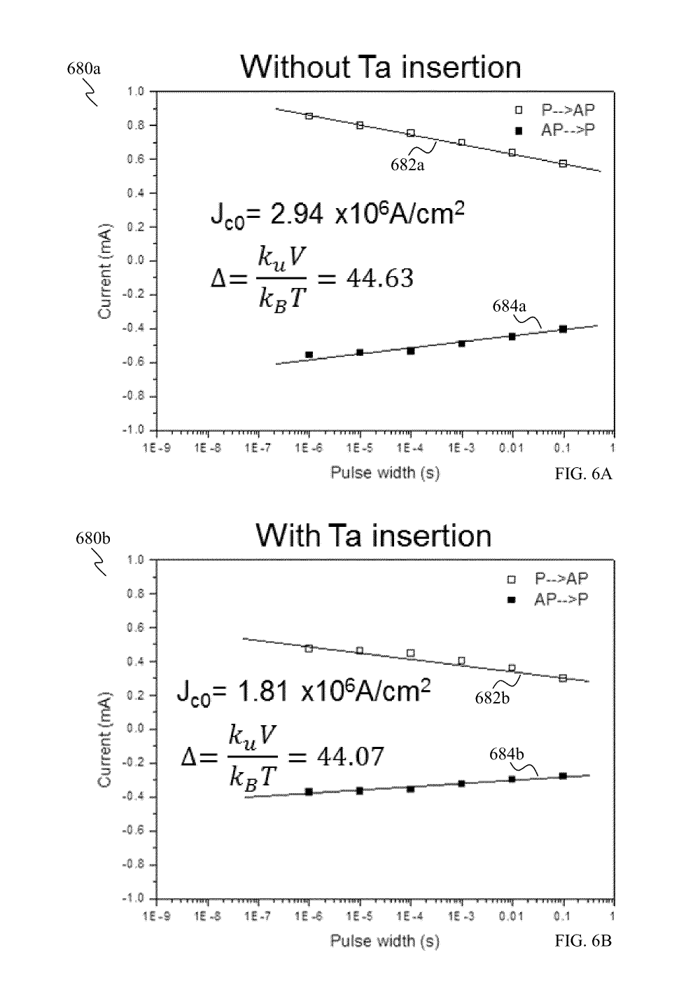

FIGS. 6A and 6B show plots (or measurements) 680a, 680b of current versus pulse width for the magnetoresistive devices 300a, 300b of the embodiments of FIGS. 3A and 3B respectively, illustrating the spin-transfer torques driven switching data.

Plot 680a, corresponding to the magnetoresistive device 300a without a tantalum (Ta) dusting layer, shows result 682a for switching from a parallel (P) state to an anti-parallel (AP) state (i.e. P→AP) and result 684a for switching from an anti-parallel (AP) to a parallel (P) state (i.e. AP→P).

Plot 680b, corresponding to the magnetoresistive device 300b a tantalum (Ta) dusting layer 322b, shows result 682b for switching from a parallel (P) state to an anti-parallel (AP) state (i.e. P→AP) and result 684b for switching from an anti-parallel (AP) to a parallel (P) state (i.e. AP→P).

As indicated in FIGS. 6A and 6B, the magnetoresistive device 300a may exhibit a switching current density, J_{c0}, of about 2.94 MA/cm², while the magnetoresistive device 300b may exhibit a switching current density, J_{c0}, of about 1.81 MA/cm². The magnetoresistive device 300b may exhibit an intrinsic switching current density, J_{c0}, that is a reduction of about 38% compared to that of the magnetoresistive device 300a. The thermal stability factors are good, with Δ=44.63 for the magnetoresistive device 300a and Δ=44.07 for the magnetoresistive device 300b. There is no substantial loss of Δ for the magnetoresistive device 300b compared to the magnetoresistive device 300a.

Averaged measurement data, based on at least 5 devices on each wafer, corresponding to the magnetoresistive device 300a having a CoFeB free layer 304 with a thickness of about 1.8 nm and without a tantalum (Ta) dusting layer insertion, indicate a mean switching current density (J_{c0}) of about 3 MA/cm², a mean thermal stability (Δ or KᵤV/k_{B}T) of about 40.7 and a mean spin torque switching efficiency ((KᵤV/k_{B}T)/J_{c0}) of about 13.51.

Averaged measurement data, based on at least 5 devices on each wafer, corresponding to the magnetoresistive device 300b having a CoFeB free layer 304 with a thickness of about 1.8 nm and with a 0.5 nm thick tantalum (Ta) dusting layer insertion, indicate a mean switching current density (J_{c0}) of about 2.04 MA/cm², a mean thermal stability (Δ or KᵤV/k_{B}T) of about 41.3 and a mean spin torque switching efficiency ((KᵤV/k_{B}T)/J_{c0}) of about 20.

The switching current density (J_{c0}) of the magnetoresistive device 300b is a reduction of approximately 30% in comparison to that of the magnetoresistive device 300a. The switching current density (J_{c0}) of the magnetoresistive device 300b is a reduction of approximately 42% in comparison with the best reported data so far of J_{c} of about 3.5 MA/cm² at 1 ns for a conventional device. Further, there is minimal or no substantial decrease of the thermal stability. Other parameters, including the thermal stability factor and the TMR, of the magnetoresistive devices of various embodiments do not appear to be degraded.

The magnetoresistive device of various embodiments, having a MgO system, may exhibit interfacial electronic structures or states that are different from a magnetoresistive device having an aluminium oxide system. The magnetoresistive device having a MgO system, and a magnetoresistive device having an aluminium oxide system, may show very different spin-orbit interactions, and the magnetoresistive device having the MgO system may be expected to possess a stronger effect and thus to assist the free magnetic layer switching in the design of various embodiments more effectively.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A magnetoresistive device comprising:
a free magnetic layer structure having a magnetization orientation that is variable; and
a spin orbit coupling structure comprising:
a tunnel barrier comprising a metal oxide; and
a metal layer, wherein the tunnel barrier and the metal layer are arranged one over the other,
wherein the spin orbit coupling structure is adapted to generate, in response to an applied current, a field to interact with the free magnetic layer structure for switching the magnetization orientation of the free magnetic layer structure.

2. The magnetoresistive device as claimed in claim 1, wherein the spin orbit coupling structure is arranged in between the free magnetic layer structure and an electrode of the magnetoresistive device.

3. The magnetoresistive device as claimed in claim 1, wherein the spin orbit coupling structure is arranged in contact with the free magnetic layer structure.

4. The magnetoresistive device as claimed in claim 1, wherein the tunnel barrier is arranged proximal to the free magnetic layer structure.

5. The magnetoresistive device as claimed in claim 1, wherein the spin orbit coupling structure has a width that is at least substantially similar to a width of the free magnetic layer structure.

6. The magnetoresistive device as claimed in claim 1, further comprising:
a first electrode; and
a second electrode,
wherein the spin orbit coupling structure and the free magnetic layer structure are arranged in between the first and second electrodes, and
wherein the spin orbit coupling structure is arranged in between the free magnetic layer structure and the first electrode.

7. The magnetoresistive device as claimed in claim 6, wherein the spin orbit coupling structure is arranged in contact with the first electrode.

8. The magnetoresistive device as claimed in claim 1, wherein the metal layer comprises at least one of tantalum, platinum, palladium or gold.

9. The magnetoresistive device as claimed in claim 1, wherein the metal oxide comprises magnesium oxide.

10. The magnetoresistive device as claimed in claim 1, wherein the spin orbit coupling structure further comprises an additional metal layer, wherein the tunnel barrier is arranged in between the metal layer and the additional metal layer.

11. The magnetoresistive device as claimed in claim 10, wherein the additional metal layer is arranged proximal to the free magnetic layer structure.

12. The magnetoresistive device as claimed in claim 10, wherein the additional metal layer is arranged in contact with the free magnetic layer structure.

13. The magnetoresistive device as claimed in claim 10, wherein the additional metal layer has a thickness that is less than a thickness of the metal layer.

14. The magnetoresistive device as claimed in claim 10, wherein the additional metal layer has a thickness in a range of between about 0.1 nm and about 1.0 nm.

15. The magnetoresistive device as claimed in claim 10, wherein the additional metal layer comprises at least one of tantalum, platinum, palladium or gold.

16. The magnetoresistive device as claimed in claim 1, wherein the tunnel barrier has a thickness in a range of between about 0.5 nm and about 1.0 nm.

17. The magnetoresistive device as claimed in claim 1, further comprising:
a fixed magnetic layer structure having a fixed magnetization orientation, wherein the fixed magnetic layer structure and the free magnetic layer structure are arranged one over the other.

18. The magnetoresistive device as claimed in claim 1, wherein the magnetoresistive device comprises a spin-transfer torque magnetic random access memory.

19. A method of forming a magnetoresistive device, the method comprising:
forming a free magnetic layer structure a magnetization orientation that is variable; and
forming a spin orbit coupling structure comprising:
a tunnel barrier comprising a metal oxide; and
a metal layer, wherein the tunnel barrier and the metal layer are arranged one over the other,
wherein the spin orbit coupling structure is adapted to generate, in response to an applied current, a field to interact with the free magnetic layer structure for switching the magnetization orientation of the free magnetic layer structure.

20. The method as claimed in claim 19, wherein the spin orbit coupling structure further comprises an additional metal layer, wherein the tunnel barrier is arranged in between the metal layer and the additional metal layer.
